(19) United States
(12) Patent Application Publication
(10) Pub. No.: US 2014/0217398 A1
(43) Pub. Date: Aug. 7, 2014

(54) THIN-FILM TRANSISTOR DEVICE AND THIN-FILM TRANSISTOR DISPLAY APPARATUS

(71) Applicants: National Sun Yat-sen University, Kaohsiung (TW); InnoLux Corporation, Jhu-Nan (TW)

(72) Inventors: Ting-Chang CHANG, Kaohsiung (TW); Yu-Chun CHEN, Kaohsiung (TW); Tien-Yu HSIEH, Kaohsiung (TW); Cheng-Hsu CHOU, Jhu-Nan (TW); Jung-Fang CHANG, Jhu-Nan (TW)

(73) Assignees: National Sun Yat-sen University, Kaohsiung (TW); InnoLux Corporation, Jhu-Nan (TW)

(21) Appl. No.: 14/138,880

(22) Filed: Dec. 23, 2013

(30) Foreign Application Priority Data
Feb. 7, 2013 (TW) 102104788

(51) Int. Cl. H01L 29/786

(52) U.S. Cl. CPC H01L 29/7869
USPC 257/43

(57) ABSTRACT

A thin-film transistor (TFT) device comprises a gate, a source, a drain, an insulation layer and an active area. The insulation layer electrically separates the gate from the source and the drain. The active area including a plurality of contacting areas contacting the source and the drain, respectively, and generates a channel including a channel width and a channel length. The active area includes a semiconductor material and has a plurality of active-area edges. In the direction parallel to the channel width, a distance between at least a contacting-area edge of the contacting areas and the active-area edge of the active area that is near to the contacting-area edge is larger than 2.5 μm and less than or equal to 16 μm. A TFT display apparatus is also disclosed.

### CROSS REFERENCE TO RELATED APPLICATIONS

This Non-provisional application claims priority under 35 U.S.C. §119(a) on Patent Application No(s). 102104788 filed in Taiwan, Republic of China on Feb. 7, 2013, the entire contents of which are hereby incorporated by reference.

### BACKGROUND OF THE INVENTION

1. Field of Invention

The invention relates to a display apparatus and, in particular, to a thin-film transistor (TFT) display apparatus and a TFT device.

2. Related Art

Thin-film transistor (TFT) devices have been widely applied to various kinds of high-level display apparatuses. With the more competitiveness, the color saturation and size of the display apparatus need to be enhanced continuously, and accordingly, the electric property and stability of the TFT device thereof must be improved also. Among TFT devices, the metal oxide semiconductor (MOS) TFT can be made in a low temperature environment and is capable of a good output current characteristic, a lower leakage current and an electron mobility ten or more times higher than the amorphous silicon (a-Si) TFT. Therefore, the metal oxide semiconductor TFT can reduce the power consumption of the display apparatus and raise the operating frequency thereof. Thus, the metal oxide semiconductor TFT can promisingly replace the conventional a-Si TFT to become the mainstream driving device of the next generation display technology.

It is considered recently that the metal oxide-based TFT has a good current characteristic, but also has an electric instability problem when operated under the negative gate bias illumination stress (NBIS). Therefore, it is an important subject to provide a TFT device that can improve the electric instability problem to enhance the performance of the display apparatus.

### SUMMARY OF THE INVENTION

In view of the foregoing subject, an objective of the invention is to provide a TFT device that can improve the electric instability problem under the NBIS operation to enhance the performance of the display apparatus.

To achieve the above objective, a thin-film transistor (TFT) device according to the invention comprises a gate, a source, a drain, an insulation layer and an active area. The insulation layer electrically separates the gate from the source and the drain. The active area includes a plurality of contacting areas contacting the source and the drain, respectively, and generates a channel including a channel width and a channel length. The active area includes a semiconductor material and has a plurality of active-area edges. In the direction parallel to the channel width, a distance between at least a contacting-area edge of the contacting areas and the active-area edge of the active area that is near to the contacting-area edge is larger than 2.5 μm and less than or equal to 16 μm.

To achieve the above objective, a thin-film transistor (TFT) display apparatus according to the invention comprises a plurality of TFT devices disposed in an array. Each of the TFT devices comprises a gate, a source, a drain an insulation layer and an active area. The insulation layer electrically separates the gate from the source and the drain. The active area includes a plurality of contacting areas contacting the source and the drain, respectively, and generates a channel including a channel width and a channel length. The active area includes a semiconductor material and has a plurality of active-area edges. In the direction parallel to the channel width, a distance between at least a contacting-area edge of the contacting areas and the active-area edge of the active area that is near to the contacting-area edge is larger than 2.5 μm and less than or equal to 16 μm.

In one embodiment, the distance is larger than or equal to 3 μm and less than or equal to 12 μm.

In one embodiment, the top-view shape of the active area is a polygon, curved shape, sector or any of combinations thereof.

In one embodiment, the top-view shape of the active area is symmetric or asymmetric.

In one embodiment, the semiconductor material includes a metal oxide of at least one metal, and the metal is indium, gallium, zinc, aluminum, tin or hafnium. The metal oxide is, for example but not limited to, indium gallium zinc oxide (IGZO), hafnium indium zinc oxide (HfIZO), or their combination.

In one embodiment, the insulation layer is disposed on the gate, and the active area, the source and the drain are disposed on the insulation layer.

In one embodiment, each of the source and the drain contacts the active area through a via hole or an opening area.

As mentioned above, the shape of the active area of the TFT device according to the invention is designed, so that the distance between at least a contacting-area edge of the contacting areas and an active-area edge of the active area that is near to the contacting-area edge is larger than 2.5 μm and less than or equal to 16 μm. Thereby, when the TFT device is under the NBIS operation, the holes H generated by the illumination will be guided to the region of the active area that will not affect the threshold voltage, so that the shift amount of the threshold voltage of the TFT device under the NBIS operation is reduced. Thereby, the instability problem under the NBIS operation can be improved or eliminated and thus the display efficiency of the TFT display apparatus can be improved.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic sectional diagram of a thin-film transistor (TFT) device according to a preferred embodiment of the invention;

FIG. 2 is a top view diagram of the TFT device in FIG. 1;

FIG. 3 is a schematic diagram showing the shift of the threshold voltage of the TFT device under the NBIS operation when the distance is 2.5 μm;

FIG. 4 is a schematic diagram showing the shift of the threshold voltage of the TFT device under the NBIS operation when the distance is 16 μm;

FIG. 5 is a schematic diagram showing the shifts of the threshold voltage of the TFT device under the NBIS operation when the distance is 3 μm, 12 μm and 16 μm;

FIG. 6 is a schematic diagram showing the cause of reducing the shift of the threshold voltage;

FIGS. 7 to 9 are schematic top-view diagrams of several variations of the TFT device according to the preferred embodiment of the invention;

FIG. 10 is a schematic sectional diagram of a variation of the TFT device according to the preferred embodiment of the invention; and

FIG. 11 is a schematic diagram of a TFT display apparatus according to a preferred embodiment of the invention.

### DETAILED DESCRIPTION OF THE INVENTION

The present invention will be apparent from the following detailed description, which proceeds with reference to the accompanying drawings, wherein the same references relate to the same elements.

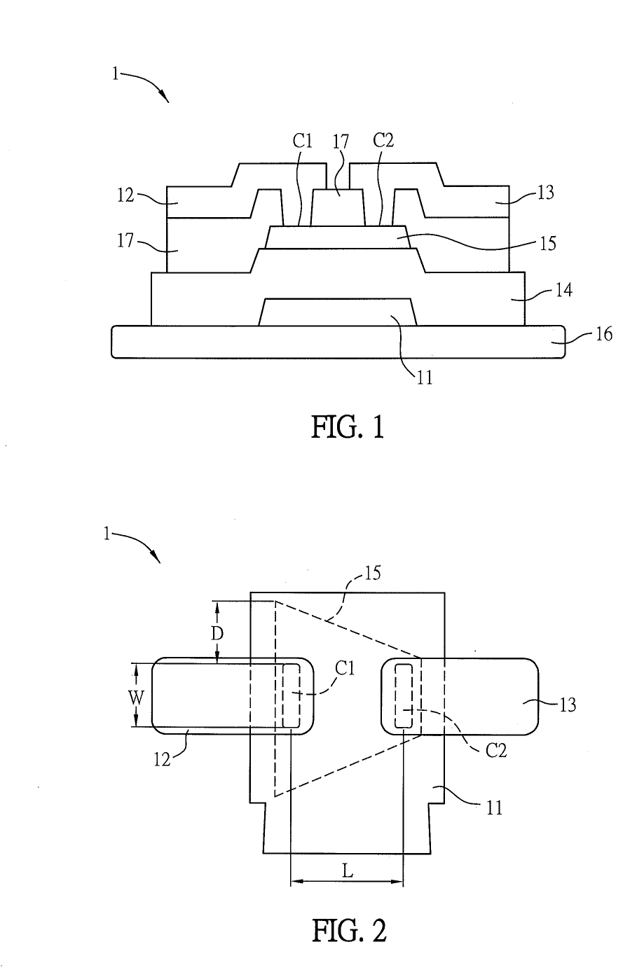

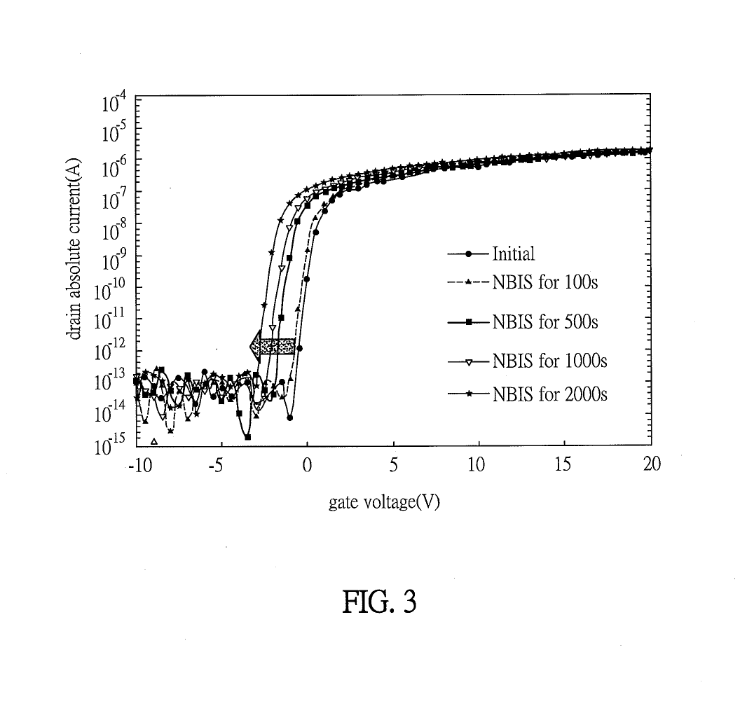

FIG. 1 is a schematic sectional diagram of a thin-film transistor (TFT) device 1 according to a preferred embodiment of the invention, and FIG. 2 is a top view diagram of the TFT device 1 in FIG. 1. As shown in FIGS. 1 and 2, the TFT device 1 includes a gate 11, a source 12, a drain 13, an insulation layer 14 and an active area 15.

In this embodiment, the gate 11 is disposed on a substrate 16. The substrate 16 is a glass substrate, or it can be made by other materials. The substrate 16 can be a flexible substrate or a rigid substrate. The material of the gate 11 includes molybdenum (Mo) or aluminum (Al) for example, or can include other kinds of metal, metal compound or the like. The insulation layer 14 is disposed on the gate 11 and covers the gate 11, functioning as a gate insulation layer. The material of the insulation layer 14 can include silicon nitride, silicon oxide or other kinds of insulation material. The active area 15 is disposed on the insulation layer 14, and can include a semiconductor material. The semiconductor material includes a metal oxide of at least one metal, and can be metal oxide semiconductor (MOS). The above-mentioned metal is such as indium, gallium, zinc, aluminum, tin or hafnium (Hf). The metal oxide is, for example but not limited to, indium gallium zinc oxide (IGZO), hafnium indium zinc oxide (HfIZO), or their combination. The metal oxide-based TFT can be made in a low temperature environment and is capable of a good output current characteristic, a lower leakage current and an electron mobility ten or more times higher than the amorphous silicon (a-Si) TFT, so as to reduce the power consumption of the display apparatus and raise the operating frequency thereof.

In this embodiment, the TFT device 1 further includes an etch stop layer (ESL) 17, which is disposed on the active area 15 and has two via holes at the active area 15. Each of the source 12 and the drain 13 is disposed on the etch stop layer 17 and partially located in the via hole. The insulation layer 14 electrically separates the gate 11 from the source 12 and drain 13. In this embodiment, the active area 15 includes a contacting area C1 contacting the source 12 and a contacting area C2 contacting the drain 13, and generates a channel. The channel has a channel width W and a channel length L, and the channel length L is larger than the channel width W in this embodiment. Herein, the source 12 and the drain 13 contact the active area 15 through the two via holes of the etch stop layer 17 to result in the contacting areas C1 and C2, respectively.

As shown in FIG. 2, in the direction parallel to the channel width W, a distance D between at least a contacting-area edge of the contacting areas (C1 for example) and the active-area edge of the active area 15 that is near (e.g. nearest) to the contacting-area edge is larger than 2.5 μm and less than or equal to 16 μm. By verification, when the distance D is increased, the instability problem of the TFT device 1 under the NBIS operation can be effectively reduced and thus the display performance can be enhanced. However, the distance D in the prior art is all designed as small as possible, i.e. under 2.5 μm, for satisfying the demand of increasing the pixel aperture ratio. Oppositely, in the invention, after discovering the effect provided by the verification, the distance D is increased to enhance the display efficiency and performance.

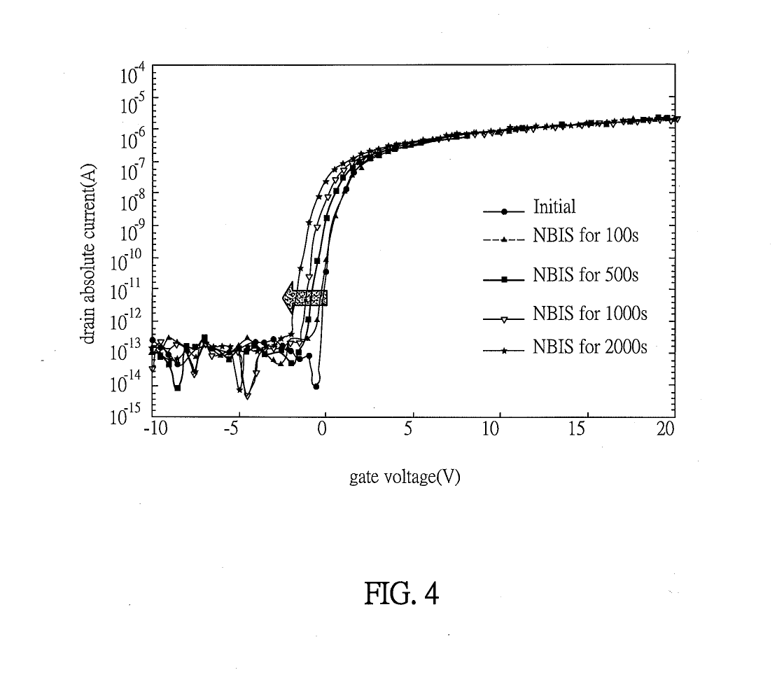

FIG. 3 is a schematic diagram showing the shift of the threshold voltage of the TFT device 1 under the NBIS operation when the distance D is 2.5 μm, and FIG. 4 is a schematic diagram showing the shift of the threshold voltage of the TFT device 1 under the NBIS operation when the distance D is 16 μm. As shown in FIGS. 3 and 4, by increasing the distance D, the shift amount of the threshold voltage under the long-term NBIS operation is effectively reduced. Thereby, the instability problem under the NBIS operation can be improved or eliminated and thus the display efficiency of the TFT display apparatus can be improved.

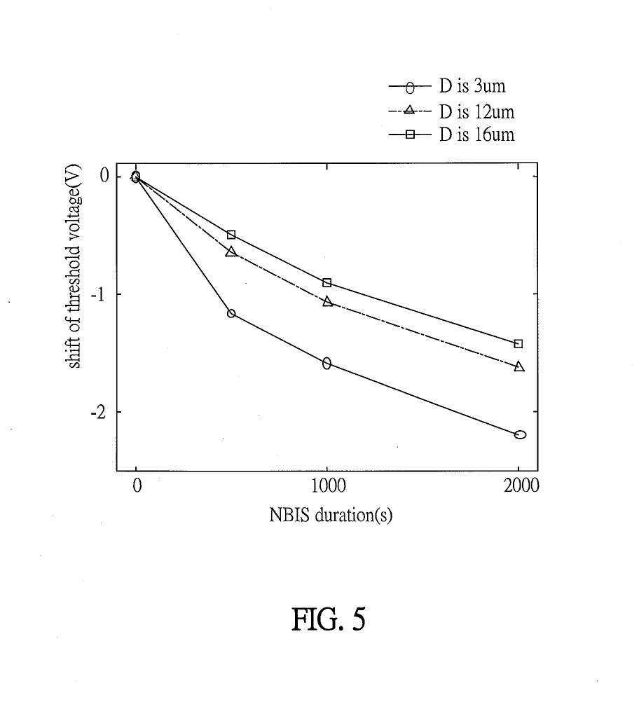

FIG. 5 is a schematic diagram showing the shifts of the threshold voltage of the TFT device 1 under the NBIS operation when the distance D is 3 μm, 12 μm and 16 μm. From FIG. 5, it can be shown that the effectiveness of reducing the shift of the threshold voltage is decreasing when the distance D is increased more and more. Therefore, also in consideration of the pixel aperture ratio, when the distance D is bounded as larger than 2.5 μm and less than or equal to 16 μm, the efficiencies of the device and display can be both optimized. Besides, it is preferable that the distance D is larger than or equal to 3 μm and less than or equal to 12 μm.

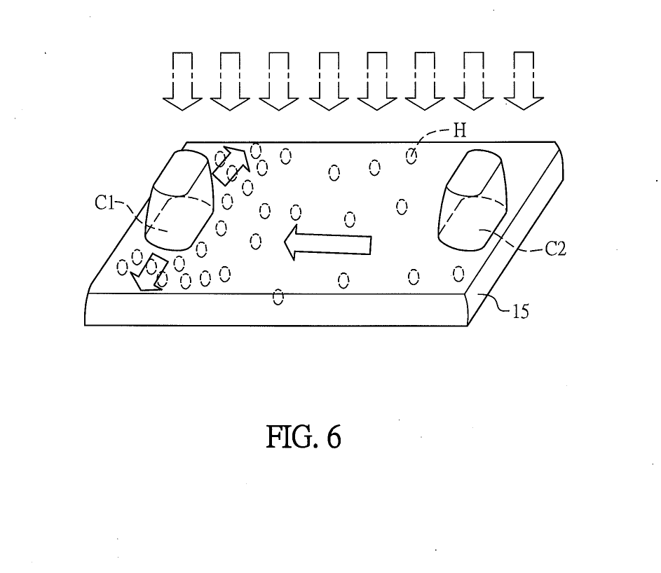

FIG. 6 is a schematic diagram showing the cause of reducing the shift of the threshold voltage. As shown in FIG. 6, when the TFT device is under the NBIS operation, the holes H generated by the illumination will be guided to (such as in the arrow direction in FIG. 6) the region of the active area 15 that will not affect the threshold voltage, and thereby the shift amount of the threshold voltage of the TFT device under the NBIS operation can be reduced.

As shown in FIG. 2, a top-view shape of the active area 15 is trapezoid. In addition to the shape shown in FIG. 2, the active area 15 also can be shaped otherwise as long as the distance D between at least a contacting-area edge of the contacting areas and the active-area edge of the active area 15 that is near (e.g. nearest) to the contacting-area edge is larger than 2.5 μm and less than or equal to 16 μm. Some examples are illustrated as below.

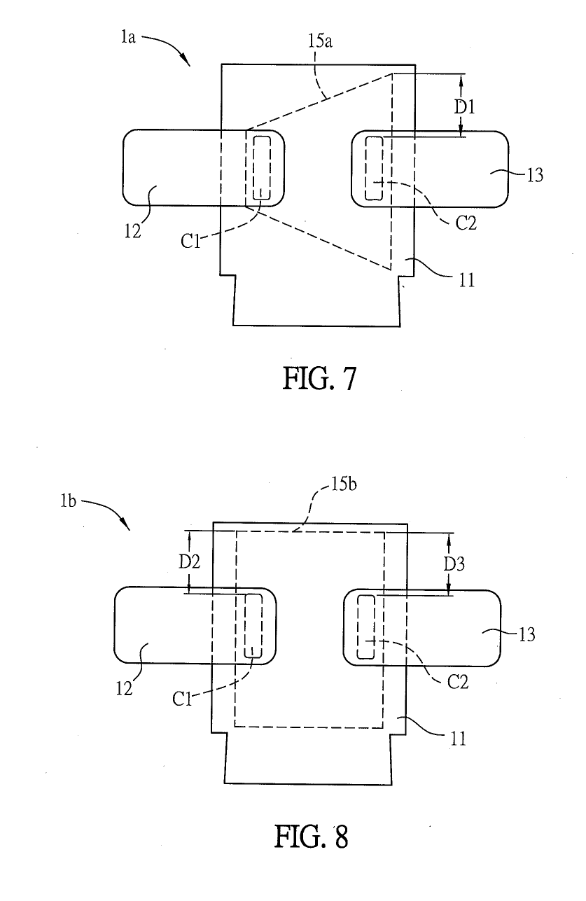

As shown in FIG. 7, the active area 15a of the TFT device 1a has another shape, so that the distance D1 between a contacting-area edge of the contacting area C2 (caused by the contact between the drain 13 and the active area 15a) and the active-area edge of the active area 15a that is near (e.g. nearest) to the contacting-area edge is larger than 2.5 μm and less than or equal to 16 μm.

As shown in FIG. 8, the active area 15b of the TFT device 1b has another shape, so that the distance D2 between a contacting-area edge of the contacting area C1 (caused by the contact between the source 12 and the active area 15b) and the active-area edge of the active area 15b that is near (e.g. nearest) to the contacting-area edge is larger than 2.5 μm and less than or equal to 16 μm. Besides, the distance D3 between a contacting-area edge of the contacting area C2 (caused by the contact between the drain 13 and the active area 15b) and the active-area edge of the active area 15b that is near (e.g. nearest) to the contacting-area edge is larger than 2.5 μm and less than or equal to 16 μm.

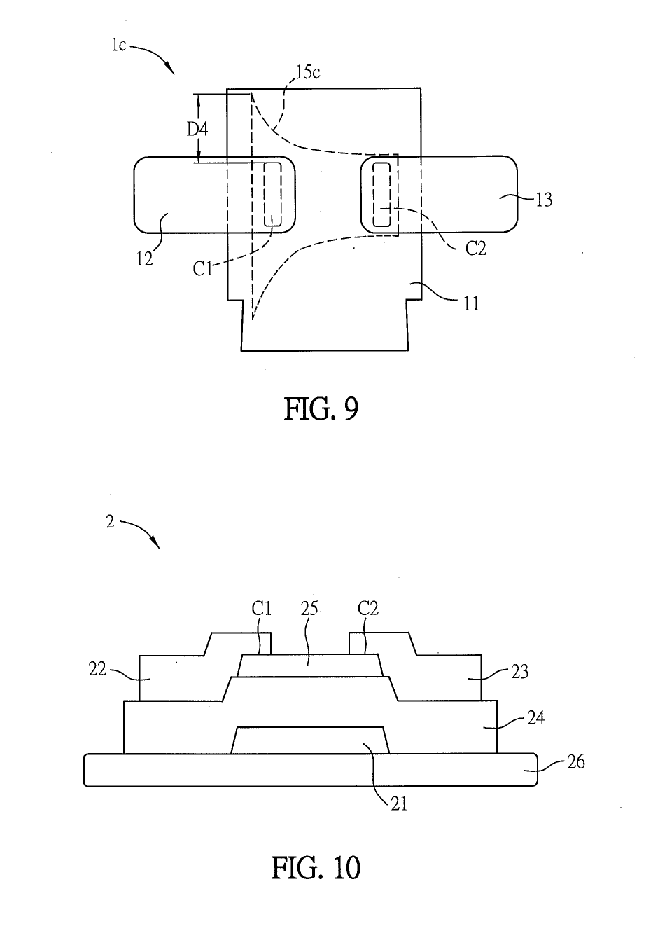

As shown in FIG. 9, the active area 15c of the TFT device 1c has another shape, so that the distance D4 between a contacting-area edge of the contacting area C1 (caused by the contact between the source 12 and the active area 15c) and the active-area edge of the active area 15c that is near (e.g. nearest) to the contacting-area edge is larger than 2.5 μm and less than or equal to 16 μm. Herein, the shape of the active area 15c includes at least a polygon and at least a curved shape.

The above-mentioned shapes of the active area are just for example. The shape of the active area for a top view can have a polygon, curved shape, sector or any of combinations thereof for example. Besides, the top-view shape of the active area can be symmetric or asymmetric. Furthermore, the distance between a contacting-area edge of any of the contacting areas and the active-area edge of the active area that is near (e.g. nearest) to the contacting-area edge can be all larger than 2.5 μm and less than or equal to 16 μm.

The sectional structure of the TFT device 1 shown in FIG. 1 is just for example but not for limiting the scope of the invention. The TFT device of the invention can have other sectional structures, and FIG. 10 shows an example as below.

As shown in FIG. 10, another TFT device 2 of the preferred embodiment of the invention includes a gate 21, a source 22, a drain 23, an insulation layer 24 and an active area 25. The gate 21 is disposed on a substrate 26. The insulation layer 24 is disposed on the substrate 26 and covers the gate 21 so as to electrically separate the gate 21 from the source 22 and drain 23. The active area 25 includes a contacting area C1 contacting the source 22 and includes a contacting area C2 contacting the drain 23, and generates a channel. The material of the active area 15 includes a metal oxide. In the direction parallel to the channel width, a distance between at least a contacting-area edge of the contacting areas and the active-area edge of the active area that is near (e.g. nearest) to the contacting-area edge is larger than 2.5 μm and less than or equal to 16 μm.

Mainly different from the TFT device 1, the TFT device 2 is not configured with an etch stop layer, and the source 22 and the drain 23 directly lie on and contact the active area 25 through the contacting areas C1 and C2, respectively, instead of through the via holes.

In this invention, the TFT device can be applied to any kind of TFT display apparatus, such as a nonself-luminous display apparatus (e.g. an LCD apparatus) or a self-luminous display apparatus (e.g. an OLED display apparatus). The LCD apparatus is taken as an example as below.

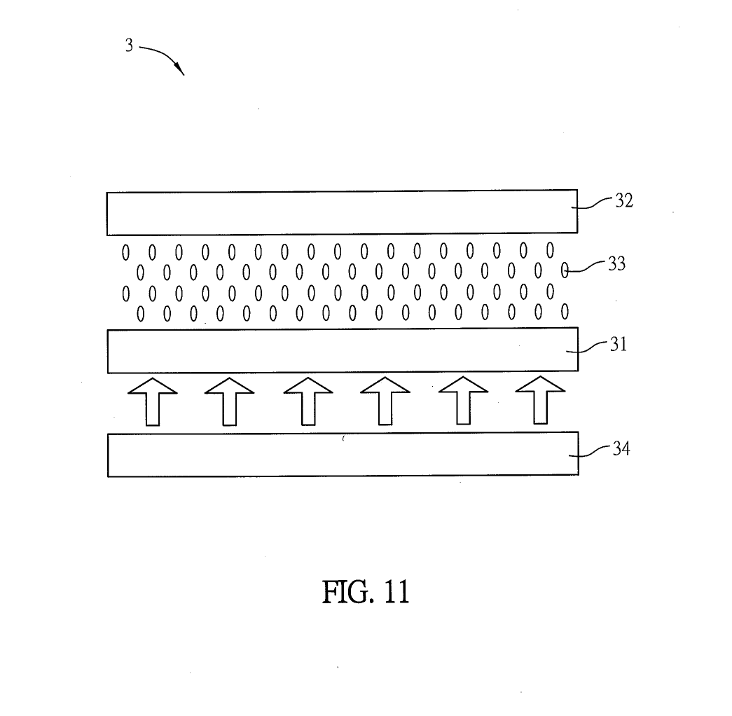

FIG. 11 is a schematic diagram of a TFT display apparatus 3 according to a preferred embodiment of the invention. As shown in FIG. 11, the TFT display apparatus 3 includes a TFT substrate 31, a color filter (CF) substrate 32, a liquid crystal layer 33 disposed between the two substrates 31 and 32, and a backlight module 34. The TFT substrate 31 and the color filter substrate 32 are disposed oppositely, and the backlight module 34 provides light for the substrates 31 and 32 and the liquid crystal layer 33 for forming images. The TFT substrate 31 includes a plurality of TFT devices, which are disposed in an array and switch on or off for the pixels. At least one of the TFT devices can be embodied by any of the TFT devices 1, 1a-1c and 2. The gate of the TFT device can be electrically connected to a scan line. Besides, the source (or drain) of the TFT device can be electrically connected to a data line while the drain (or source) can be electrically connected to a pixel electrode. By increasing the distance, the shift amount of the threshold voltage of the TFT device under the long-term operation is effectively reduced. Thereby, the instability problem under the NBIS operation can be improved or eliminated and thus the display efficiency of the TFT display apparatus can be improved.

In summary, the shape of the active area of the TFT device according to the invention is designed, so that the distance between at least a contacting-area edge of the contacting areas and the active-area edge of the active area that is near to the contacting-area edge is larger than 2.5 μm and less than or equal to 16 μm. Thereby, when the TFT device is under the NBIS operation, the holes H generated by the illumination will be guided to the region of the active area that will not affect the threshold voltage, so that the shift amount of the threshold voltage of the TFT device under the NBIS operation is reduced. Thereby, the instability problem under the NBIS operation can be improved or eliminated and thus the display efficiency of the TFT display apparatus can be improved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A thin-film transistor (TFT) device, comprising:
a gate;
a source;
a drain;
an insulation layer electrically separating the gate from the source and the drain; and
an active area having a plurality of contacting areas contacting the source and the drain, respectively, and generating a channel including a channel width and a channel length, the active area including a semiconductor material and having a plurality of active-area edges,
wherein in the direction parallel to the channel width, a distance between at least a contacting-area edge of the contacting areas and the active-area edge of the active area that is near to the contacting-area edge is larger than 2.5 μm and less than or equal to 16 μm.

2. The thin-film transistor device as recited in claim 1, wherein the distance is larger than or equal to 3 μm and less than or equal to 12 μm.

3. The thin-film transistor device as recited in claim 1, wherein the top-view shape of the active area is a polygon, curved shape, sector or any of combinations thereof.

4. The thin-film transistor device as recited in claim 1, wherein the top-view shape of the active area is symmetric or asymmetric.

5. The thin-film transistor device as recited in claim 1, wherein the semiconductor material comprises a metal oxide of at least one metal, and the metal is indium, gallium, zinc, aluminum, tin or hafnium.

6. The thin-film transistor device as recited in claim 1, wherein each of the source and the drain contacts the active area through a via hole or an opening area.

7. A thin-film transistor (TFT) display apparatus, comprising:
a plurality of TFT devices disposed in an array, each of the TFT devices comprising:
a gate;
a source;
a drain;
an insulation layer electrically separating the gate from the source and the drain; and
an active area having a plurality of contacting areas contacting the source and the drain, respectively, and generating a channel including a channel width and a channel length, the active area including a semiconductor material and having a plurality of active-area edges,
wherein in the direction parallel to the channel width, a distance between at least a contacting-area edge of the contacting areas and the active-area edge of the active area that is near to the contacting-area edge is larger than 2.5 μm and less than or equal to 16 μm.

8. The thin-film transistor display apparatus as recited in claim 7, wherein the distance is larger than or equal to 3 μm and less than or equal to 12 μm.

9. The thin-film transistor display apparatus as recited in claim 7, wherein the top-view shape of the active area is a polygon, curved shape, sector or any of combinations thereof.

10. The thin-film transistor display apparatus as recited in claim 7, wherein the top-view shape of the active area is symmetric or asymmetric.
